(19) United States
(12) Patent Application Publication
(10) Pub. No.: US 2012/0025838 A1
(43) Pub. Date: Feb. 2, 2012

(54) SUNLIGHT SIMULATOR

(76) Inventors: Ching-Lin LEE, Taoyuan County (TW); I-Fan Chang, Taoyuan County (TW); Ming-Chieh Lin, Taoyuan County (TW)

(21) Appl. No.: 12/905,161

(22) Filed: Oct. 15, 2010

(30) Foreign Application Priority Data
Jul. 28, 2010 (TW) 099124944

(51) Int. Cl. G01R 31/26; G01R 31/00

(52) U.S. Cl. 324/501

(57) ABSTRACT

A sunlight simulator and solar cell measuring device consisting of detecting device is disclosed, in which the housing is a closed space consisting of an opening gate, the closed space is internally installed with a light source which is used to emit a light toward the opening gate, and a splitting unit is installed on the travelling path of the light for dividing the light into a first light-beam and a second light-beam, herein the first light-beam is projected onto the solar cell under measurement located at the opening gate as a solar cell measuring device; in addition, a detecting device is installed on the travelling path of the second light-beam for receiving the second light-beam, and then a signal can be outputted by the detecting device in order to monitor the irradiation variation of the light emitted by the light source, thus ensuring the precision of the solar cell measurement.

### BACKGROUND OF THE INVENTION

1. Field of the Invention

The present invention generally relates to a sunlight simulator and solar cell measuring device consisting of detecting device; in particular, the present invention relates to a sunlight simulator or a solar cell measuring device internally equipped with a detecting device thereby monitoring the irradiation intensity of a beam emitted by an internal light source.

2. Description of Related Art

At present, the solar cell power generation system is produced by means of semiconductor processes, whose power generation principle lies in that solar daylight is allowed to radiate on the solar cell such that the solar cell absorbs the incident sunlight energy thereby generating electron to create current due to semiconductor features, and transferring the created current to the load via conducting lines.

Therefore, after completion of solar cell manufacture processes, it is required to evaluate the performance of power generation capability in the solar cell. In case the fabricated solar cell demonstrates good conversion output features, the solar cell manufacturer can exploit more competitive price advantage in market; but the determination for such output features essentially follows the photoelectric conversion efficiency

$$( η = \frac{{V}_{m} \times {I}_{m}}{{p}_{in}} \times 100 \% ,$$

where V indicates voltage at the maximum output power, I indicates current at the maximum output power and P indicates value of the maximum output power) which is obtained by measuring the current-voltage curve of the solar cell subject to sunlight exposure. The conversion efficiency in the solar cell represents a ratio of the energy collected by photoelectric conversions from sunlight to electricity against the energy from sunlight radiation within one day; for example, at noon from March to September, the solar radiation energy at a location near the equator of earth is measured approximately 1000 W/m², so the standard solar radiation energy (i.e. AM1.5G) may generate the energy of 1000 W/m²; hence for a solar cell having an area of 1 meter squared and featuring the conversion efficiency of 15%, a peak energy of roughly 150 Watts can be thus generated at noon in March or September along the equator.

Consequently, measurement of the power generation feature in solar cells is crucial; whereas the irradiation of sunlight may fluctuate due to many factors like variations in sunlight radiation caused by weather changes and so on, the industry thus typically uses a sunlight simulator 101 to simulate the required sunlight. In operation, a simulated beam 1011 is respectively projected onto a solar cell 102 under measurement and a monitor cell 103 located outside of the sunlight simulator 101 in order to perform the output feature measurement on the solar cell 102 under measurement; the externally installed monitor cell 103 is used to perform the irradiation measurement on the beam so as to monitor the intensity thereof (see FIG. 1).

However, in the above-mentioned beam irradiation measurement, since it is necessary to simultaneously project the beam onto the solar cell under measurement and the monitor cell, such an operation needs at least two opening gates or otherwise one single bigger opening gate, thus consequently, forcing the sunlight simulator to use an internal light source of higher power so as to provide sufficiently uniform light radiation onto both the solar cell under measurement and the monitor cell, which adversely affects the output feature of the solar cell. In addition, since the price for such a type of light source may be proportional to the effective brightness and illumination area thereof, the manufacture cost becomes a disadvantageous factor in such an approach.

As a result, it is desirable to provide a solution of a sunlight simulator or solar cell measuring device having beam irradiation measuring device internally installed which allows to advantageously reduce the required manufacture cost of light source in an automatic field.

### SUMMARY OF THE INVENTION

An objective of the present invention is to provide a sunlight simulator and solar cell measuring device consisting of detecting device wherein a detecting device for beam irradiation measurement is installed inside of the sunlight simulator.

Another objective of the present invention is to provide a sunlight simulator and solar cell measuring device consisting of detecting device wherein a detecting device for beam irradiation measurement is installed inside of the solar cell measuring device.

Yet another objective of the present invention is to provide a sunlight simulator and solar cell measuring device consisting of detecting device which allows to reduce the range of the opening gate and to prevent the use of the high-power light source featuring wider illumination range thereby lessening the manufacture cost for the sunlight simulator or the solar cell measuring device.

In order to achieve the objectives set forth as above, a sunlight simulator and solar cell measuring device consisting of detecting device according to the present invention is provided wherein the housing is a closed space consisting of an opening gate, the closed space is internally installed with a light source which is used to emit a light toward the opening gate, and a splitting unit is installed on the travelling path of the light for dividing the light into a first light-beam and a second light-beam, herein the first light-beam is projected toward the opening gate, and a collimating lens can be installed at the location of the opening gate for projecting the first light-beam onto the solar cell under measurement as a solar cell measuring device; in addition, a detecting device is installed on the travelling path of the second light-beam for receiving the second light-beam, then a signal can be outputted by the detecting device in order to monitor the intensity of the light emitted by the light source thereby ensuring the precision of solar cell measurement.

Specifically, the aforementioned splitting unit is a planar splitter and the detecting device is a solar cell or a semiconductor chip.

Specifically, at least one filter is installed between the above-said light source and detecting device, in which the type of the filter is a filter enabling passing of a particular wavelength or alternatively a filter enabling blocking of ultra-violet (UV) ray.

Specifically, an integrating device is installed between the above-said light source and detecting device which allows the light emitted by the light source to become uniform.

Specifically, a shutter is installed between the above-said light source and detecting device which enables separation of the light source in case the light source is not in use.

Specifically, the above-said light source can be any one of a set of light emitting diodes (LEDs), a xenon lamp, a halogen lamp or a combination thereof, and additionally a condenser is installed on one side of the light source thereby converging the light of the light source.

Specifically, a reflecting device is further installed inside of the above-said housing for reflecting out the first light-beam at an angle toward the opening gate.

Specifically, the present invention further comprises a conversion efficiency analyzing device which is used to receive the conversion signal outputted by the detecting component and to calculate and compare with a current-voltage (I-V) curve for output.

Furthermore, another implementation approach can be also applied in which a transmission detecting device is directly installed on the travelling path of the light of the light source, the surface of the transmission detecting device is installed with a detecting component used to detect light signal and to convert the light signal into a conversion signal for output thereby detecting the irradiation of the light and accordingly eliminating the use of the splitting unit as illustrated in the previous embodiment.

### BRIEF DESCRIPTION OF THE DRAWINGS

FIG. 1 shows a diagram for the operation of a prior art solar cell measuring device;

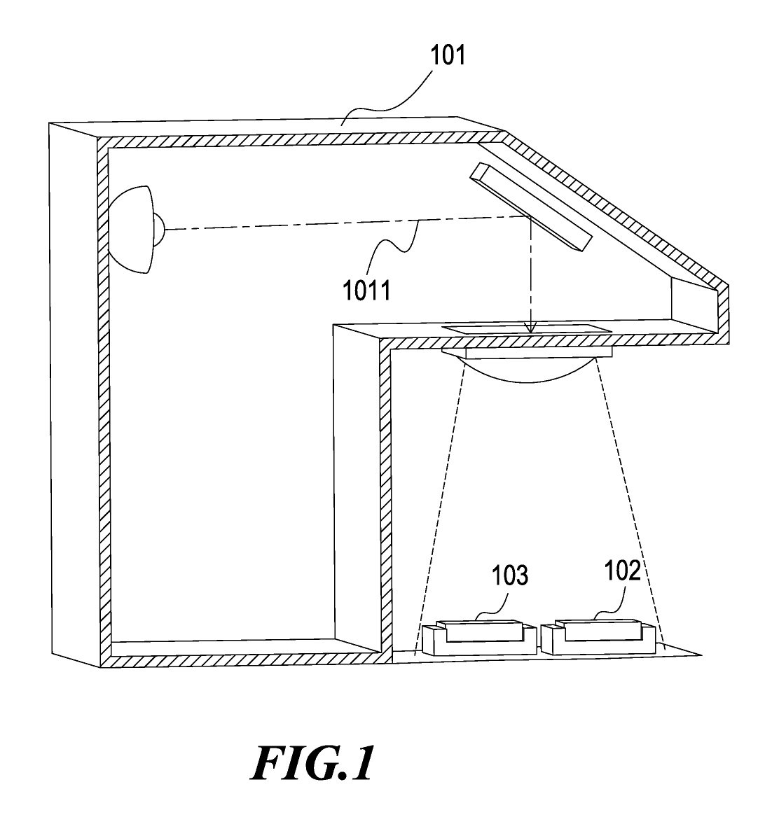

FIG. 2 shows a diagram for the operation of a first embodiment of a sunlight simulator and solar cell measuring device consisting of detecting device according to the present invention;

FIG. 3A shows a diagram for the structure of a second embodiment of a sunlight simulator and solar cell measuring device consisting of detecting device according to the present invention;

FIG. 3B shows a diagram for the operation of the second embodiment of a sunlight simulator and solar cell measuring device consisting of detecting device according to the present invention;

FIG. 3C shows a diagram for the operation of a third embodiment of a sunlight simulator and solar cell measuring device consisting of detecting device according to the present invention;

FIG. 4A shows a diagram for the operation of a fourth embodiment of a sunlight simulator and solar cell measuring device consisting of detecting device according to the present invention;

FIG. 4B shows a diagram for the operation of a fifth embodiment of a sunlight simulator and solar cell measuring device consisting of detecting device according to the present invention;

FIG. 5 shows a diagram for the implementation architecture of a sunlight simulator and solar cell measuring device consisting of detecting device according to the present invention; and

FIG. 6 shows a diagram for AM1.5G current-voltage (I-V) curve of a sunlight simulator and solar cell measuring device consisting of detecting device according to the present invention.

### DETAILED DESCRIPTION OF THE PREFERRED EMBODIMENTS

The aforementioned and miscellaneous technical contents, aspects and effects of the present invention can be hereunder clearly presented by referring to the detailed descriptions for the preferred embodiments of the present invention in conjunction with appended drawings.

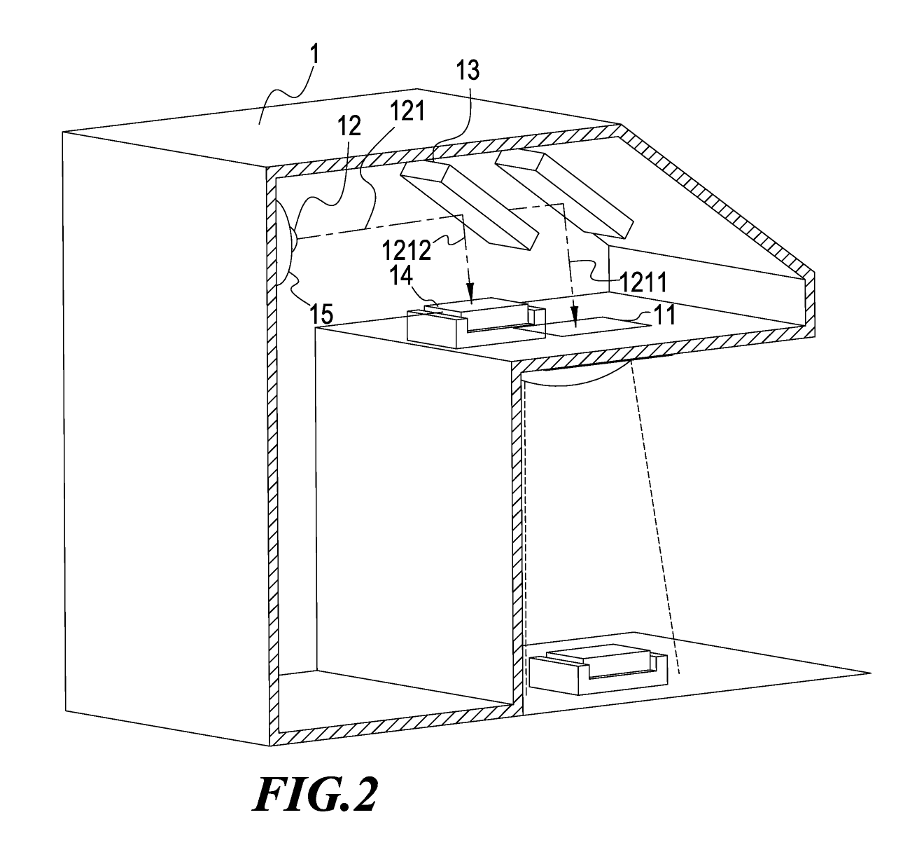

Refer first to FIG. 2, wherein a diagram for the operation of a first embodiment of a sunlight simulator and solar cell measuring device consisting of detecting device according to the present invention is shown. From the Figure, it can be seen that the sunlight simulator comprises:

a housing 1, which is a closed space consisting of an opening gate 11;

a light source 12, which is installed inside of the housing 1 for consistently emitting a light 121 toward the opening gate 11 and formed by any one of a set of light emitting diodes (LEDs), a xenon lamp, a halogen lamp or a combination thereof;

a splitting unit 13, which is installed on the travelling path of the light 121 emitted by the light source 12 for dividing the light 121 into a first light-beam 1211 and a second light-beam 1212, herein the first light-beam 1211 is projected toward the opening gate 11, and additionally the splitting unit 13 is a planar splitter;

a detecting device 14, which is installed on the travelling path of the second light-beam 1212 for receiving the second light-beam 1212, then a signal can be outputted by the detecting device 14 in order to monitor the irradiation of the light 121 emitted by the light source 12, and additionally the detecting device 14 is a solar cell or a semiconductor chip.

It should be noticed that a condenser 15 can be installed on one side of the light source 12 thereby converging the light 121 emitted by the light source 12.

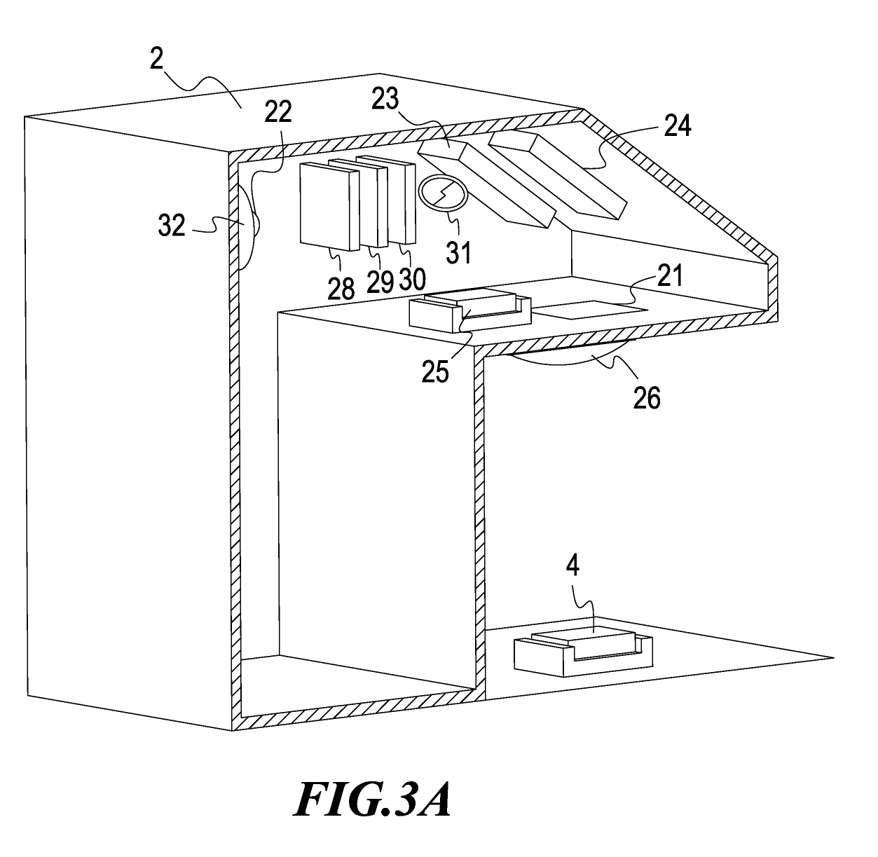

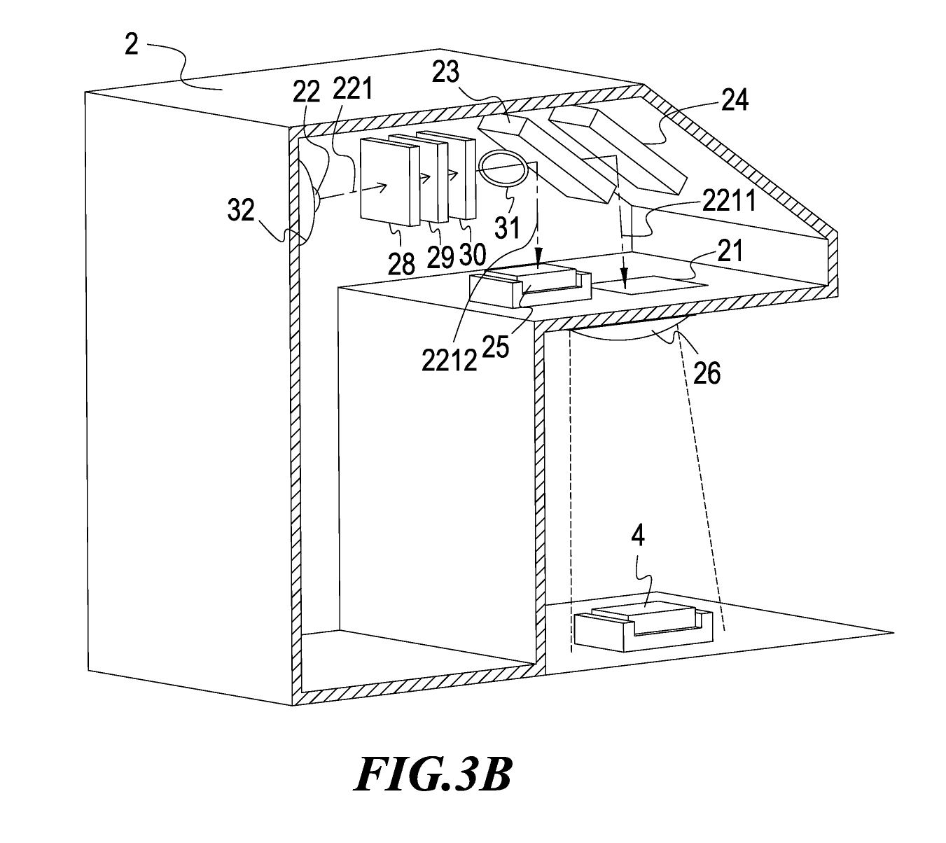

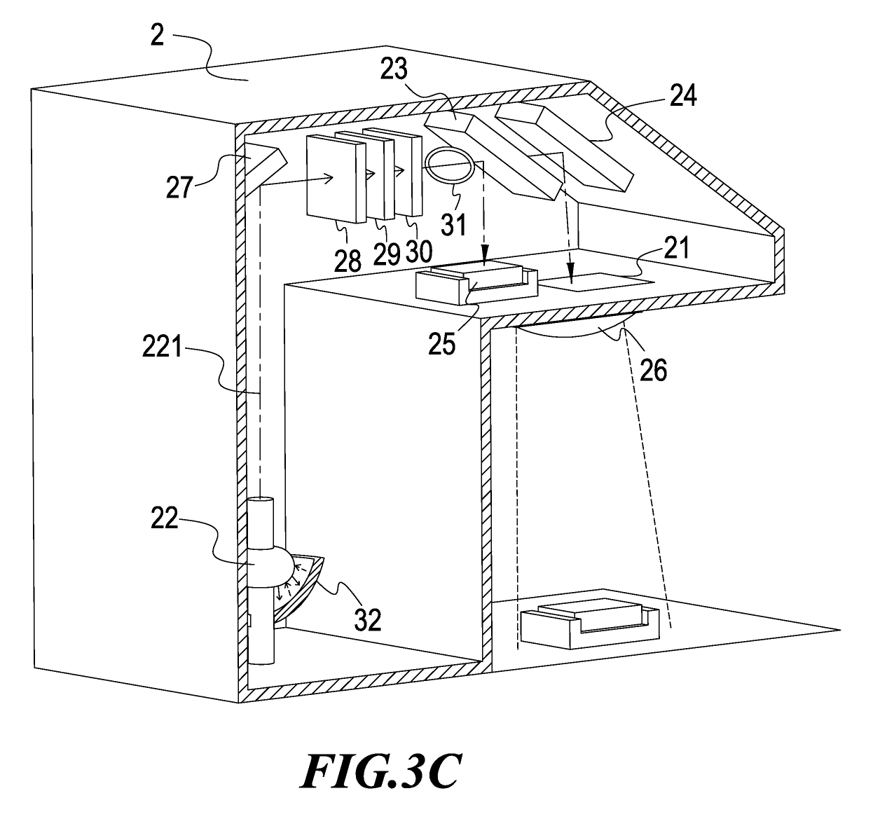

Refer next to FIGS. 3A and 3B, wherein diagrams for the structure and the operation of a second embodiment of a sunlight simulator and solar cell measuring device consisting of detecting device according to the present invention are respectively shown. From these Figures, it can be seen that the solar cell measuring device outputs a simulated light source to a solar cell under measurement 4, and the solar cell measuring device comprises:

a housing 2, which is a closed space consisting of an opening gate 21;

a light source 22, which is installed inside of the housing 2 for consistently emitting a light 221 toward the opening gate 21 and formed by any one of a set of light emitting diodes (LEDs), a xenon lamp, a halogen lamp or a combination thereof;

a splitting unit 23, which is installed on the travelling path of the light 221 emitted by the light source 22 for dividing the light 221 into a first light-beam 2211 and a second light-beam 2212, and additionally the splitting unit 23 is a planar splitter;

a first reflecting device 24, which is installed inside of the housing 2 for reflecting out the first light-beam 2211 at an angle toward the opening gate 21;

a detecting device 25, which is installed on the travelling path of the second light-beam 2212 for receiving the second light-beam 2212, and then a conversion signal can be outputted by the detecting device 25 in order to monitor the irradiation of the light 221 emitted by the light source 22;

a collimating lens 26, which is installed at the location of the opening gate 21 of the housing 2 for projecting the first light-beam 2211 onto the solar cell under measurement 4.

It should be noticed that in case the light source 22 is not installed at a position parallel to the splitting unit 23, it is possible to additionally place a second reflecting device 27 inside of the housing 2 thereby reflecting out the light 221 emitted by the light source 22 at an angle toward the splitting unit 23 (see FIG. 3C).

It should be noticed that an air-mass 1.5G (AM1.5G) filter 28 can be installed between the light source 22 and the splitting unit 23 thereby only allowing specific wavelength(s) in the light 221 emitted by the light source 22 to pass through in order to make the spectrum output be close to actual sunlight. Furthermore, “AM1.5G” means the average daylight irradiation of sunlight incident at 45 degrees onto the surface of earth. Consequently, if the solar cell is used at other places, the sunlight incident angle may vary; that is, a filter of different air-mass value (representing the average daylight irradiation of sunlight onto the surface of earth incident at different angle) should be applied.

It should be noticed that an ultra-violet (UV) filter 29 can be installed between the light source 22 and the splitting unit 23 thereby eliminating the UV ray in the light 221.

It should be noticed that an integrating device 30 can be installed between the light source 22 and the splitting unit 23 thereby making the light 221 become uniform.

It should be noticed that a shutter 31 can be installed between the light source 22 and the splitting unit 23 thereby enabling separation of the light 221 emitted by the light source 22 without shutting down electric power in case the light source 22 is not in use so as to prevent consistent temperature elevation in the component.

It should be noticed that a condenser 32 can be installed on one side of the light source 22 thereby converging the light 221 emitted by the light source 22.

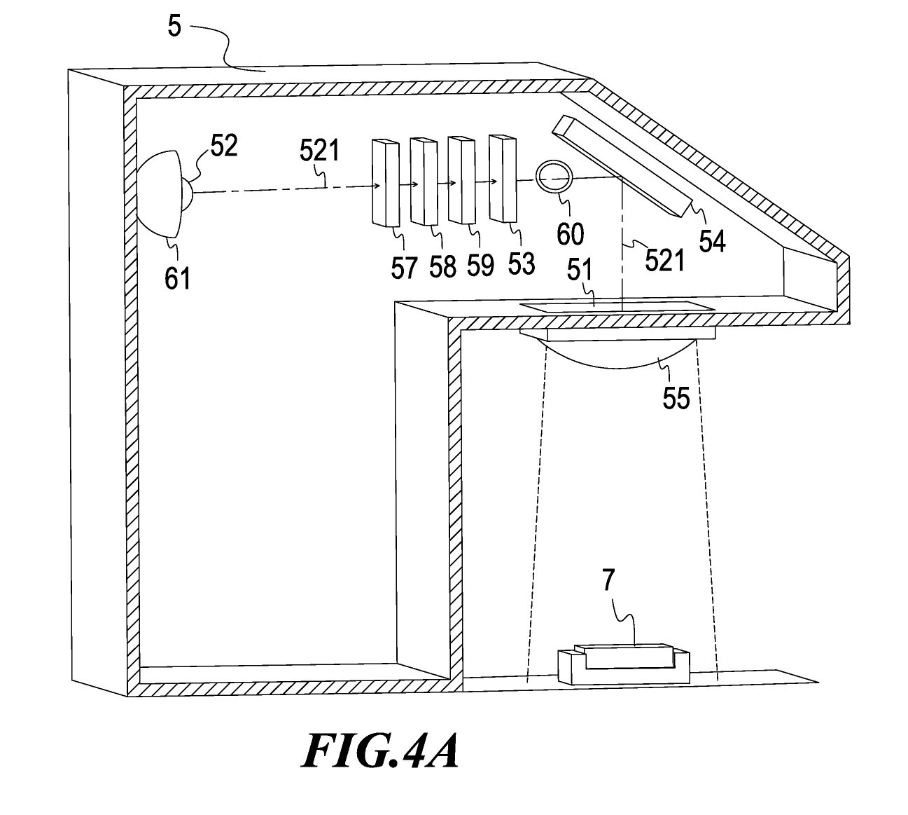

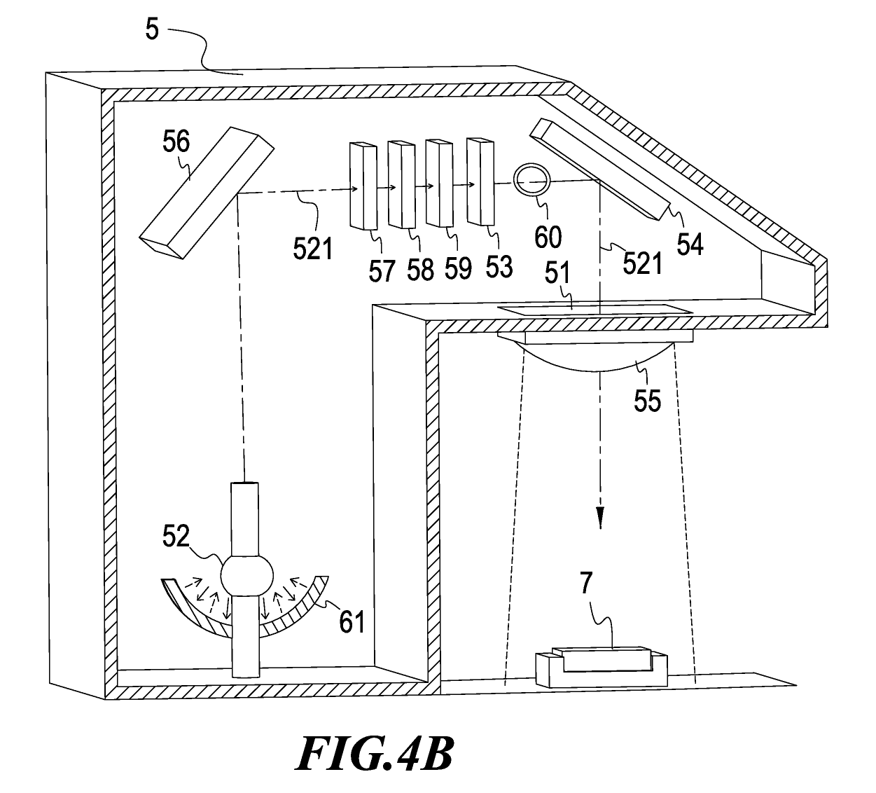

Refer now to FIG. 4A, wherein a diagram for the operation of a fourth embodiment of a sunlight simulator and solar cell measuring device consisting of detecting device according to the present invention is shown. From the Figure, it can be seen that the sunlight simulator comprises:

a housing 5, which is a closed space consisting of an opening gate 51;

a light source 52, which is installed inside of the housing 5 for consistently emitting a light 521 toward the opening gate 51 and formed by any one of a set of light emitting diodes (LEDs), a xenon lamp, a halogen lamp or a combination thereof;

a transmission detecting device 53, which is installed on the travelling path of the light 521 emitted by the light source 52 for receiving the light 521 and allows the light 521 to pass through the transmission detecting device 53. A detecting component is installed on the surface of the transmission detecting device 53 thereby monitoring the irradiation of the light 521 emitted by the light source 52 and converting the light signal into a conversion signal for output.

It should be noticed that a first reflecting device 54 can be installed inside of the housing 5 for reflecting out the light 521 passing through the transmission detecting device 53 at an angle toward the opening gate 51.

It should be noticed that a collimating lens 55 can be installed at the location of the opening gate 51 of the housing 5 for projecting the light 521 onto the solar cell under measurement 7.

It should be noticed that in case the light source 52 is not installed at a position parallel to the transmission detecting device 53, it is possible to additionally place a second reflecting device 56 inside of the housing 5 thereby reflecting out the beam 521 emitted by the light source 52 at an angle toward the transmission detecting device 53 (see FIG. 4B).

It should be noticed that an air-mass 1.5G (AM1.5G) filter 57 can be installed between the light source 52 and the transmission detecting device 53 thereby only allowing the specific wavelength(s) in the light emitted by the light source to pass through in order to make the spectrum output be close to actual sunlight.

It should be noticed that an ultra-violet (UV) filter 58 can be installed between the light source 52 and the transmission detecting device 53 thereby eliminating the UV ray in the light 521.

It should be noticed that an integrating device 59 can be installed between the light source 52 and the transmission detecting device 53 thereby making the light 521 become uniform.

It should be noticed that a shutter 60 can be installed between the light source 52 and the transmission detecting device 53 thereby enabling separation of the light 521 emitted by the light source 52 without shutting down electric power in case the light source 52 is not in use, so as to prevent consistent temperature elevation in the component and also prolong the lifespan of the light source 52, further reducing maintenance requirements and lessening operation costs.

It should be noticed that a condenser 61 can be installed on one side of the light source 52 thereby converging the light 521 emitted by the light source 52.

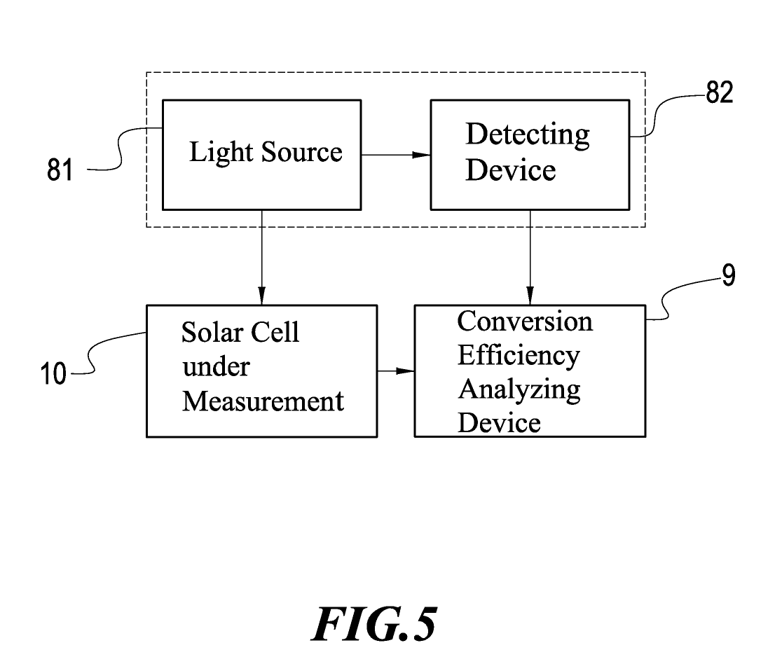

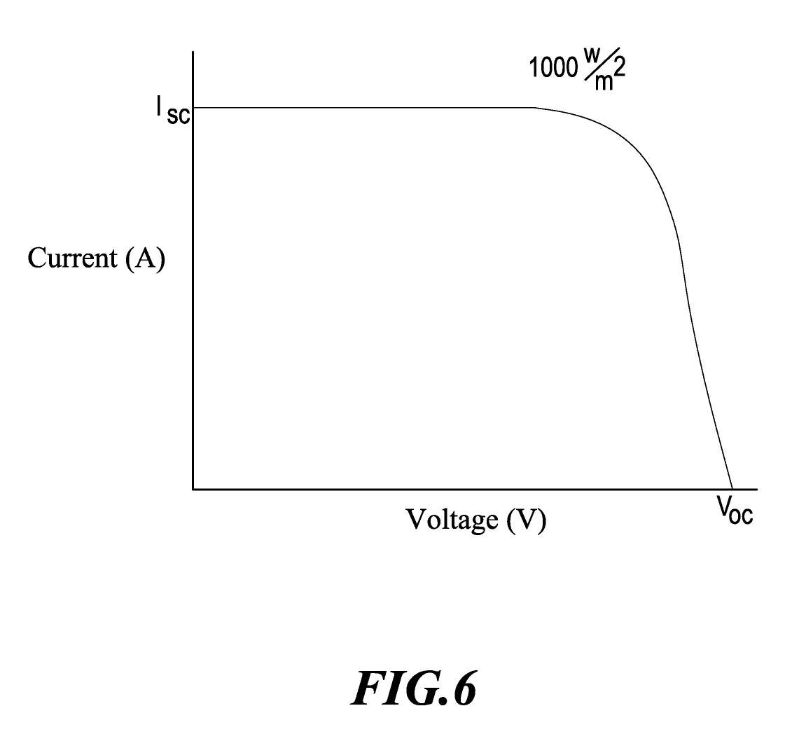

Refer to FIG. 5, wherein a block diagram of a preferred application embodiment is shown, illustrating the implementation architecture of a sunlight simulator and solar cell measuring device consisting of detecting device according to the present invention, and obtain results of higher precision in provides by conversion efficiency analyzing device as shown in FIG. 6. Herein, after reception of the beam from the light source 81 by the detecting device 82 in either the sunlight simulator or the solar cell measuring device, a detection signal can be consistently outputted through photoelectric conversion to the conversion efficiency analyzing device 9; at the same time, after reception of the beam from the light source 81 by the solar cell under measurement 10, an electrical signal can be also consistently outputted through photoelectric conversion to the conversion efficiency analyzing device 9. The conversion efficiency analyzing device 9 accordingly calculates the ratio of light source irradiation variation in the light source 81 based on the aforementioned detection signal and the standard I-V curve, then performs operations on the obtained ratio and the electrical signal from the solar cell under measurement 10 in order to compensate or correct the light source irradiation variation in the light source 81 occurring during the lighting process thereby reducing the influence of the light source irradiation variation in the simulator on the measurement; after such a compensation or correction operation, it is possible to reduce one thirds or half of the variation for the conversion efficiency measure values of the solar cell under measurement, further achieving the objectives of platform cost reduction and measure quality enhancement.

The disclosed sunlight simulator and solar cell measuring device consisting of detecting device according to the present invention, in comparison with other prior art technologies, provides the following advantages:

1. in accordance with the present invention, a detecting device for beam irradiation measurement is installed inside of the sunlight simulator and solar cell measuring device which reduces the size of the opening gate and also lessens manufacture costs of the sunlight simulator or solar cell measuring device;

2. in accordance with the present invention, a beam irradiation signal of detection is transferred to a conversion efficiency analyzing device and the conversion efficiency analyzing device performs correction operations in order to increase the measure precision of the solar cell under measurement;

3. by mean of such precision improvements, with the pricing standard based on the conversion efficiency of solar cells in current market, the sales price of solar cells after categorization can be advantageously reflected.

The descriptions of the aforementioned preferred embodiments according to the present invention are to better illustrate the characteristics and spirit of the present invention, rather than using the above-disclosed preferred embodiments to limit the scope thereof. It is intended that all effectively equivalent changes, alternations or modifications are deemed to be included within the scope of the present invention delineated by the claims set forth as below.

What is claimed is:

1. A sunlight simulator consisting of detecting device, comprising:
a housing, which is a closed space consisting of an opening gate;
a light source, which is installed inside of the housing for consistently emitting a light toward the opening gate;
a splitting unit, which is installed on a travelling path of the light emitted by the light source for dividing the light into a first light-beam and a second light-beam, herein the first light-beam is projected toward the opening gate; and
the detecting device, which is installed on a travelling path of the second light-beam for receiving the second light-beam, and then outputs a conversion signal.

2. The sunlight simulator consisting of detecting device according to claim 1, wherein the light source is any one of a set of light emitting diodes (LEDs), a xenon lamp, a halogen lamp or a combination thereof.

3. The sunlight simulator consisting of detecting device according to claim 1, wherein the detecting device is any one of a solar cell or a semiconductor chip.

4. The sunlight simulator consisting of detecting device according to claim 1, further comprising a conversion efficiency analyzing device which receives the conversion signal outputted by the detecting device and calculates a beam irradiation variation ratio of the light source.

5. A solar cell measuring device consisting of a detecting device, which outputs a simulated light source to a solar cell under measurement, which the solar cell measuring device comprising:
a housing, which is a closed space consisting of an opening gate;
a light source, which is installed inside of the housing for consistently emitting a light toward the opening gate;
a splitting unit, which is installed on a travelling path of the light emitted by the light source for dividing the light into a first light-beam and a second light-beam;
at least one reflecting device, which is installed inside of the housing for reflecting out the first light-beam at an angle toward the opening gate;
a detecting device, which is installed on a travelling path of the second light-beam for receiving the second light-beam, and then outputs a conversion signal; and
a collimating lens, which is installed at a location of the opening gate of the housing for projecting the first light-beam onto the solar cell under measurement.

6. The solar cell measuring device consisting of detecting device according to claim 5, wherein a filter is installed between the light source and the splitting unit such that a particular wavelength in the light emitted by the light source is allowed to pass.

7. The solar cell measuring device consisting of detecting device according to claim 6, wherein the filter is an air-mass 1.5G (AM1.5G) filter allowing a spectrum output of the light similar (indefinite??) to actual sunlight.

8. The solar cell measuring device consisting of detecting device according to claim 5, wherein an ultra-violet (UV) filter is installed between the light source and the splitting unit thereby eliminating a UV ray in the light.

9. The solar cell measuring device consisting of detecting device according to claim 5, wherein an integrating device is installed between the light source and the splitting unit thereby making the light emit uniformly (indefinite??).

10. The solar cell measuring device consisting of detecting device according to claim 5, wherein a shutter is installed between the light source and the splitting unit which enables separation of the light source without shutting down electric power in case the light source is not in use thereby preventing consistent temperature elevation in the component.

11. The solar cell measuring device consisting of detecting device according to claim 5, wherein the light source is any one of a set of light emitting diodes (LEDs), a xenon lamp, a halogen lamp or a combination thereof.

12. The solar cell measuring device consisting of detecting device according to claim 5, wherein the splitting unit is a planar splitter.

13. The solar cell measuring device consisting of detecting device according to claim 5, wherein a condenser is installed on one side of the light source thereby converging the light of the light source.

14. The solar cell measuring device consisting of detecting device according to claim 5, wherein inside of the housing further comprises another reflecting device for reflecting out the light of the light source at an angle toward the splitting unit.

15. The solar cell measuring device consisting of detecting device according to claim 5, further comprising a conversion efficiency analyzing device which receives the conversion signal outputted by the detecting device and calculates a beam irradiation variation ratio of the light source.
